(19) United States
(12) Patent Application Publication
(10) Pub. No.: US 2024/0305288 A1
(43) Pub. Date: Sep. 12, 2024

(54) Asymmetric Device Size Stacking

(71) Applicant: Finwave Semiconductor, Inc., Belmont, MA (US)

(72) Inventor: Raul Alidio, Carlsbad, CA (US)

(21) Appl. No.: 18/441,491

(22) Filed: Feb. 14, 2024

Related U.S. Application Data
(60) Provisional application No. 63/450,182, filed on Mar. 6, 2023.

(51) Int. Cl. H03K 17/10; H01P 1/15

(52) U.S. Cl. CPC H03K 17/102; H01P 1/15

(57) ABSTRACT

A stack of transistors having equal voltage division when in the OFF state is disclosed. Rather than utilizing compensation capacitors, the present system varies the gate periphery of the transistors in the stack to achieve the desired voltage division. This may be done by varying the number of gate fingers in each transistor, by varying the gate width of the transistors or a combination of these approaches. This approach results in easier design, routing and simulation, with improved power handling.

This application claims priority of U.S. Provisional Patent Application Ser. No. 63/450,182, filed Mar. 6, 2023, the disclosure of which is incorporated herein by reference in its entirety.

### FIELD

Embodiments of the present disclosure relate to RF switching structures and more particularly, RF switching structures that utilize stacked transistor devices.

### BACKGROUND

Radio Frequency (RF) switches can use series and shunt Field Effect Transistor (FET) devices to enable RF path selection. For increased power handling, certain FET devices, such as GaN and CMOS SOI devices, for example, can be stacked in series. As devices are stacked in series, the voltage division across a multiple device stack can deviate from equal voltage division when devices are switched to their OFF state and in a shunt or series configuration.

A standard method for on-chip voltage compensation is to add capacitance. This may be in the form of lumped MIM (metal-insulator-metal) capacitors or interdigitated capacitors in parallel with each individual device until equal voltage division is achieved. However, depending on the capacitive value required for compensation, these lumped element capacitors may either be large in terms of the physical layout dimensions or not physically achieved when capacitive values are small.

Therefore, it would be beneficial if there were a RF switch structure that achieved equal or roughly equal voltage division along the device stack but did not require lumped capacitive elements to achieve this.

### SUMMARY

A stack of transistors having equal voltage division when in the OFF state is disclosed. Rather than utilizing compensation capacitors, the present system varies the gate periphery of the transistors in the stack to achieve the desired voltage division. This may be done by varying the number of gate fingers in each transistor, by varying the gate width of the transistors or a combination of these approaches. This approach results in easier design, routing and simulation, with improved power handling.

According to one embodiment, a semiconductor structure is disclosed. The semiconductor structure comprises a stack of transistors connected in series, each having at least one drain region, at least one source region and one or more gate fingers; and wherein a number of gate fingers is not constant for all transistors in the stack. In some embodiments, the number of gate fingers is selected such that a voltage across each transistor in the stack is roughly equal when the transistors are in an OFF state. In some embodiments, the source region of a last transistor is connected directly or indirectly to ground and has a second number of gate fingers, and a first transistor in the stack is furthest from the last transistor and has a first number of gate fingers, and wherein the first number is greater than the second number. In some embodiments, there is at least one transistor in series between the first transistor and the last transistor, having a number of gate fingers that is between the first number and the second number, inclusive. In certain embodiments, number of gate fingers in each transistor decreases moving from the first transistor to the last transistor. In some embodiments, the semiconductor structure comprises a shunt transistor stack. In some embodiments, the semiconductor structure comprises a series transistor stack.

According to another embodiment, a semiconductor structure is disclosed. The semiconductor structure comprises a stack of transistors connected in series, each having a gate width, at least one drain region, at least one source region and one or more gate fingers; and wherein the gate width is not constant for all transistors in the stack. In some embodiments, the gate width is selected such that a voltage across each transistor in the stack is roughly equal when the transistors are in an OFF state. In some embodiments, the source region of a last transistor is connected directly or indirectly to ground and has a second gate width and a first transistor in the stack is furthest from the last transistor and has a first gate width, and wherein the first gate width is greater than the second gate width. In certain embodiments, there is at least one transistor in series between the first transistor and the last transistor, having a gate width that is between the first gate width and the second gate width, inclusive. In certain embodiments, the gate width of each transistor decreases moving from the first transistor to the last transistor. In some embodiments, the semiconductor structure comprises a shunt transistor stack. In some embodiments, the semiconductor structure comprises a series transistor stack. In some embodiments, a number of gate fingers is constant for all transistors in the stack. In other embodiments, a number of gate fingers is not constant for all transistors in the stack. In certain embodiments, the last transistor has a second number of gate fingers and a first transistor has a first number of gate fingers, and wherein the first number of gate fingers is greater than the second number of gate fingers.

### BRIEF DESCRIPTION OF THE FIGURES

For a better understanding of the present disclosure, reference is made to the accompanying drawings, which are incorporated herein by reference and in which:

FIG. 1 shows a single pole, double throw (SPDT) switch;

FIG. 2 shows an equivalent circuit of FIG. 1 when a first port is selected;

FIG. 3A shows a stack of transistors;

FIG. 3B shows an equivalent circuit of FIG. 3A when in the OFF state;

FIG. 4 shows the voltage across a stack of four transistors having equal capacitance;

FIG. 5A shows the voltage across a stack of four transistors having unequal capacitance;

FIG. 5B shows the voltage across a stack of four transistors having equal capacitance;

FIG. 6 shows additional capacitance added to the transistors in the stack to achieve equal capacitance;

FIG. 7 shows a transistor with multiple gate fingers;

FIGS. 8A-8B show two transistors with different numbers of gate fingers;

FIG. 9A shows a stack of four transistors;

FIG. 9B shows an actual topology of a stack of four transistors having equal capacitance and different number of gate fingers;

FIG. 10A shows a stack of three transistors; and

FIG. 10B shows an actual topology of the stack of three transistors having equal capacitance and different gate widths.

### DETAILED DESCRIPTION

Embodiments of the present disclosure relate to RF switching structures. These RF switching structures may be fabricated using GaN or CMOS silicon on insulator (SOI) technologies.

FIG. 1 shows a RF switching structure in the form of a single pole double throw (SPDT) switch 1. The SPDT switch 1 has an input 2 (which may be a signal labelled RFc), and a first output 3 (RF1) and a second output 4 (RF2). Two series transistors are used to select either the first output 3 or the second output 4. Specifically, the selection of an output is determined based on the voltage applied to the first select signal 9 (V1) and the second select signal 10 (V2).

When the first select signal 9 is grounded and the second select signal 10 has a positive voltage, first series transistor 5 is open while second series transistor 6 is closed. Thus, the input signal RFc becomes available at the first output 3. The SPDT switch 1 also includes a first shunt transistor 7 and a second shunt transistor 8. In the above configuration, the first shunt transistor 7 is open, while the second shunt transistor 8 is closed. Thus, the second output 4 is grounded due to the second shunt transistor 8.

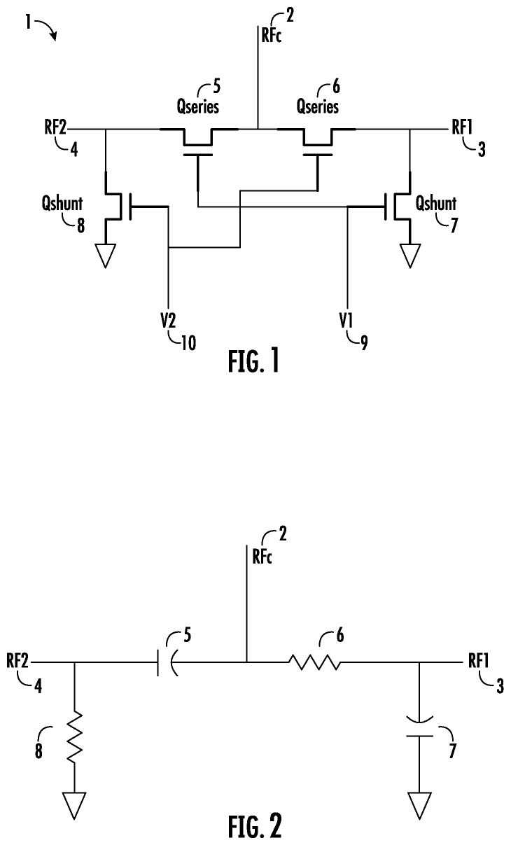

FIG. 2 shows an equivalent circuit when the first output 3 is selected. Closed transistors are modeled as resistors, while open transistors are modeled as capacitors. Note that first shunt transistor 7, which acts as a capacitor has a voltage difference across it that is roughly equal to the input signal (RFc). Similarly, first series transistor 5 also has a voltage difference across it that is roughly equal to the input signal (RFc).

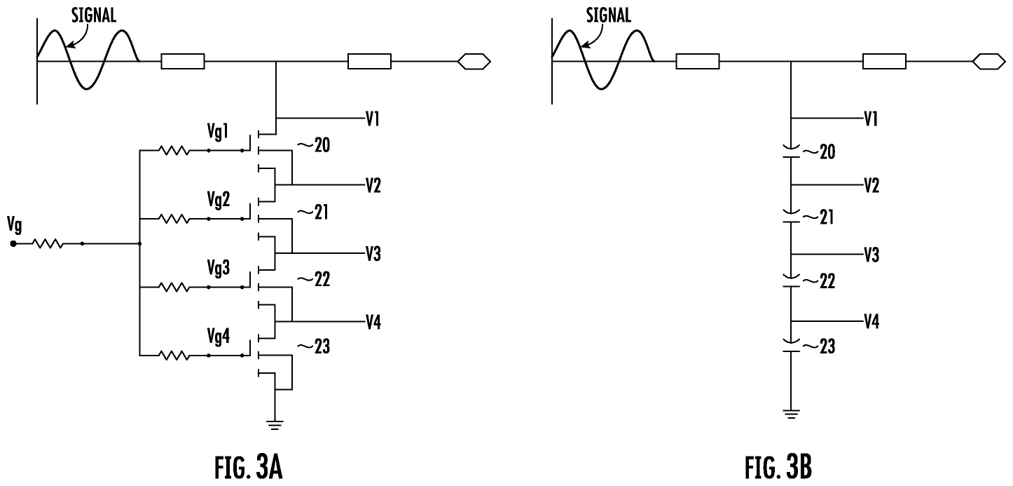

Thus, to increase RF input power handling and device reliability, the series and shunt transistor devices, like those shown in FIG. 1, can be stacked in series. In FIG. 3A, a stack of four shunt transistor devices 20,21,22,23 is shown. This stack may be used in place of first shunt transistor 7, for example. The input to the gate of each of the stacked shunt capacitors is the same, while the drain of one transistor is connected to the source of an adjacent transistor. The shunt transistor devices, when biased in the OFF-State, take the brunt of the RF input power and must be able to handle the incoming voltage swing as devices near breakdown voltages, where Vgd/Vsg voltage swings are no longer linear.

FIG. 3B is the equivalent OFF-State COFF capacitance representation of each shunt transistor device. The labelled voltages V1-V4 represent the voltage measured at the drain of each of the shunt transistor devices.

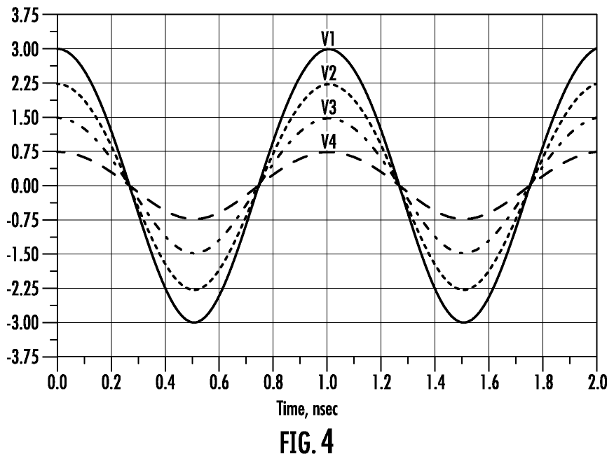

With equal capacitance across each device (Cdg and Cgs), the RF voltage swing is then ideally spread equally across the stack height as shown in FIG. 4, where a sample 6V peak to peak signal is spread equally across a stack of 4 transistor devices, with a difference of 1.5 Vpp between device nodes.

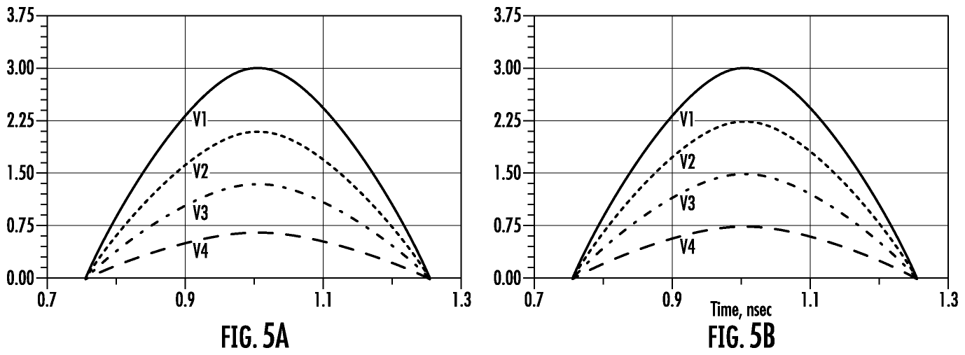

However, in the physical circuit layout, parasitic elements due to the physical device layout and the number of the transistor devices stacked in series (also referred to as stack height) may alter the voltage division across the stack. Capacitive compensation is then needed to recover the equal voltage division. FIG. 5A shows the difference of a simulated time varying signal when the stack is not capacitively compensated. In contrast, FIG. 5B shows a stack that is capacitively compensated to achieve equal voltage division. The drain voltages of each device in the stack are depicted as V1, V2, V3, V4, and are cross referenced to FIGS. 3A-3B. The slight voltage division difference (V1−V2≠V2−V3≠V3−V4) in FIG. 5A will alter the device power handling and will result in lower linearity performance, such as lower 1 dB compression point. When viewing voltage swing across shunt transistor device 20 (see FIG. 3A), this early compression occurs when Vg1−V2 (also denoted as Vsg) is a larger delta than V1−Vg1 (also denoted as Vgd) and will reach a non-linear voltage swing earlier than having equal Vgd/Vsg.

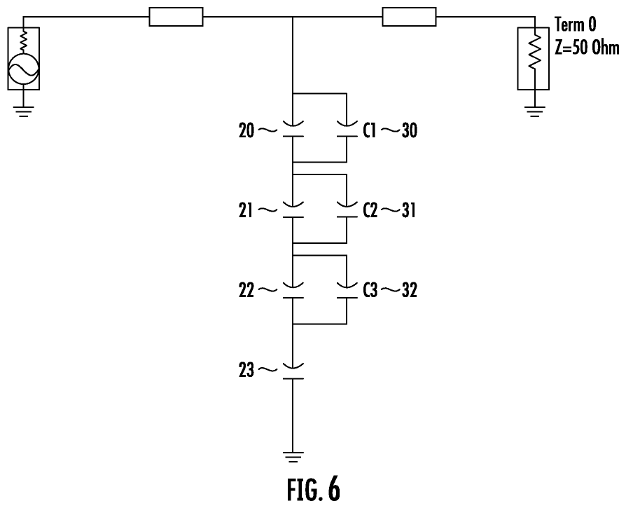

In the prior art, the addition of lumped element capacitance such as MIM capacitors or interdigitated capacitors can be used as compensation elements. FIG. 6 shows compensation capacitance 30, 31, 32 that can be added in parallel to each transistor device 20, 21, 22, 23 in the stack. Depending on the capacitive value required for compensation, these lumped element capacitors may either be large in terms of the physical layout dimensions or not physically achieved when capacitive values are small.

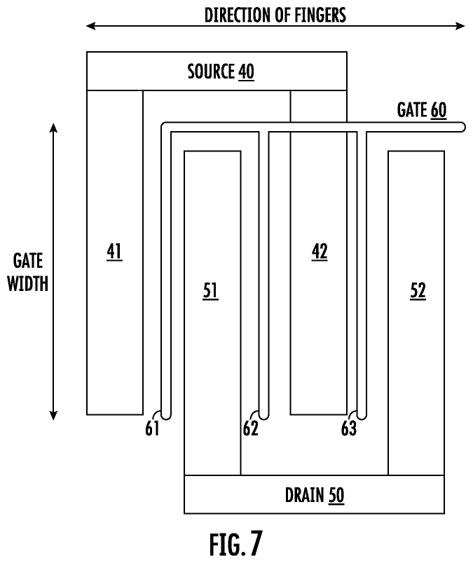

In contrast, the present disclosure uses transistor gate sizing as a means for adding capacitive compensation. As shown in FIG. 7, each transistor has a source region 40, a drain region 50 and a gate 60 disposed between the source region 40 and drain region 50. In some embodiments, the transistor device may be fabricated with a plurality of alternating source regions and drain regions. FIG. 7 shows two drain regions 51, 52 interdigitated with two source regions 41, 42. In this embodiment, the gate 60 may include a plurality of fingers 61, 62, 63. Each finger 61, 62, 63 is disposed at a boundary between a source region 41, 42 and an adjacent drain region 51, 52. Further, these fingers are parallel to one another. The gate of the transistor has an area, which is typically referred to as the gate periphery. This gate periphery is related to the gate width. The gate width is defined as the direction perpendicular to the direction of the fingers. Additionally, the gate periphery is related to the number of fingers. Specifically, the gate area, or periphery, is typically expressed as the number of fingers multiplied by the gate width.

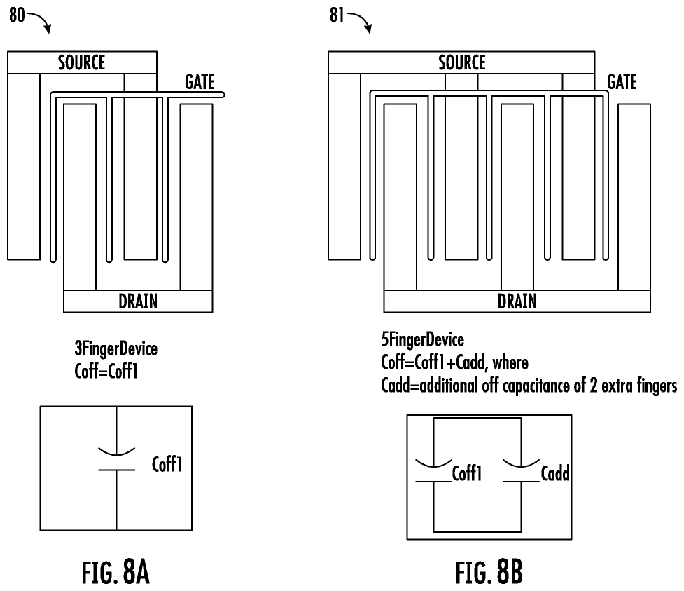

These extra fingers may improve ON state resistance. However, these additional fingers also add to the OFF state capacitance. This is shown in FIGS. 8A-8B. FIG. 8A shows the three finger transistor 80 of FIG. 7. The OFF state capacitance of this three finger transistor 80 may be expressed as C_{OFF1}. FIG. 8B shows a transistor fabricated with five fingers. The OFF state capacitance of this five finger transistor 81 may be expressed as C_{OFF1}+C_{ADD}, wherein C_{OFF1} is the capacitance of the three finger transistor and C_{ADD} is additional capacitance resulting from the additional fingers.

It is this increase in OFF state capacitance that allows capacitive compensation. Each additional finger adds OFF state capacitance. The number of fingers needed will depend on the amount of capacitance required per device until equal or roughly equal voltage division is achieved. The additional capacitance achieved with additional gate fingers is less than the area needed for an interdigitated capacitor and no additional routing is needed if an MIM capacitor can be used.

RF circuit analysis tools, such as Keysight's ADS (RF circuit simulator) in conjunction with an electromagnetic simulator such as Ansys's HFSS may be used to analyze the magnitude of the unequal voltage division of a transistor stack and may be used to determine the amount of capacitive compensation needed to achieve an equal voltage division. Of course, other tools may also be used. This information may then be used to determine the number of fingers that each transistor device in the stack may have.

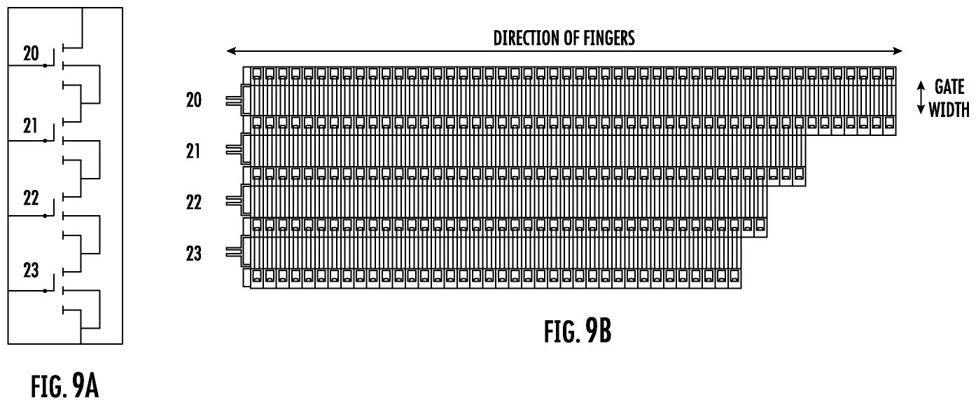

FIG. 9A shows the device stack from FIG. 3A and 6. In this embodiment, rather than adding additional compensation capacitors (as shown in FIG. 6), the additional capacitance is achieved by increasing the number of fingers in some of the transistors in the stack. Thus, the extra capacitance values C1, C2 and C3 (see FIG. 6) are now created using additional device gate fingers that increases gate periphery and in turn, capacitance. For instance, in one specific embodiment, transistor device 23 has an OFF State capacitance equal to C_{OFF}, which is achieved with 55 gate fingers (nf=55). Transistor device 22 has an OFF state capacitance of C_{OFF}+C3, which is achieved with 57 gate fingers (nf=57). Transistor device 21 has an OFF state capacitance of C_{OFF}+C2, which is achieved with 59 gate fingers (nf=59). Finally, transistor device 20 has an OFF state of C_{OFF}+C1, which is achieved with 69 gate fingers (nf=69) Note that C1>C2>C3 are the capacitances resulting from the extra gate fingers added to each corresponding device. The subsequent voltage analysis will yield the equal voltage division shown in FIGS. 4 and 5B. Thus, by varying the number of gate fingers in the transistors in the stack, the voltage across each transistor may be made roughly equal when in the OFF state. In some embodiments, the voltage across each transistor in the OFF state differs by less than 10%. In certain embodiments, the voltage across each transistor in the OFF state differs by less than 5%. In yet other embodiments, the voltage across each transistor in the OFF state differs by less than 1%.

While FIGS. 3A-3B show a shunt transistor stack, it is understood that the same technique also applies to series transistor stacks. For example, in FIG. 2, first series transistor 5 has a voltage (RFc) at its drain and is connected at ground at its source (through a resistive element). Thus, this series transistor will be subjected to the same unequal voltage division explained above.

Thus, in some embodiments, the number of gate fingers in each transistor of a device stack is varied, wherein the transistor of the stack with its source in contact with ground (either directly as with a shunt transistor stack, or indirectly through a resistive element, as with a series transistor stack), also referred to as the last transistor, has a second number of gate fingers, while the transistor with its drain in contact with the incoming RF voltage, also referred to as the first transistor in the stack, has a first number of gate fingers. As defined herein, the first transistor is the furthest transistor from the last transistor in the stack. The first number of gate fingers is greater than the second number of gate fingers. Further, the transistors disposed between the first transistor and the last transistor in the stack may have a number of gate fingers that is between the first number and the second number, inclusive. In some embodiments, the number of gate fingers decreases or remains the same for each transistor moving from the first transistor toward the last transistor. In certain embodiments, the number of gate fingers decreases for each transistor moving from the first transistor toward the last transistor. Further, note that is certain embodiments, the gate width of all of the transistors is the same, while the different numbers of gate fingers create transistors of different gate periphery.

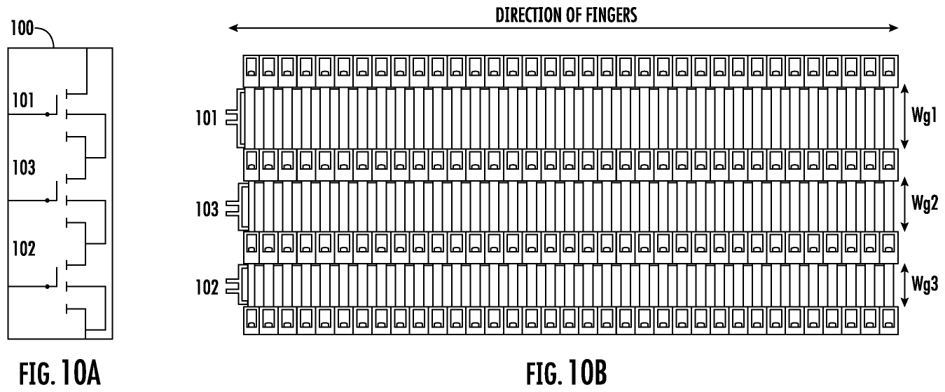

There are other ways that device sizing may be used to vary the OFF state capacitance. In another embodiment, the number of gate fingers remains constant. However, the gate width of the transistor device is changed. One such configuration is shown in FIGS. 10A-10B. In this embodiment, there is a three transistor stack 100 that includes a first transistor 101, a last transistor 102 and one transistor 103 between the first transistor 101 and the last transistor 102. FIG. 10B shows the topology of the three transistor stack 100. Note that the number of fingers in each transistors is equal (unlike the earlier embodiments), however, the gate width of the transistors varies. Specifically, the first transistor 101 has a first gate width, labelled Wg1, while the last transistor 102 has a second gate width, smaller than the first gate width, labelled Wg3. The gate width of the transistor 103 between these two transistors has a gate width (labelled Wg2) that is between the first gate width and the second gate width, inclusive. In some embodiments, the gate width decreases for each transistor, moving from the first transistor in the stack to the last transistor. In one specific embodiment, the first gate width is 35 μm, the second gate width is 20 μm and the gate width of transistor 103 is 25 μm. Of course, other gate widths are also possible and the selection of gate widths depends on many factors, including layout, incoming RF voltage, and others.

Thus, like varying the number of gate fingers, varying the gate width changes the OFF state capacitance of the transistor. Tools, such as those described above, may be used to determine an appropriate gate width for each transistor in the stack. Note that in this implementation, the number of gate fingers is equal for all of the transistors in the stack.

In yet another embodiment, the gate periphery of the transistors in the stack may be varied by modifying the number of fingers and also varying the gate width. In this embodiment, the difference in the number of fingers between the first transistor and the last transistor may be less as compared to the difference in the number of fingers between these two transistors when gate width remains constant. Additionally, the difference in gate width between the first transistor and the last transistor may be less as compared to the difference in the gate widths between these two transistors when the number of fingers remains constant.

The embodiments described above in the present application may have many advantages. The most important advantage is that with equal voltage division, there is improved power handling ability. Additionally, the ability to simulate this type of compensation is simpler than is currently done for separate compensation capacitors. Further, since only the gate periphery is being modified (as opposed to including another compensation capacitor), design and routing are simplified as well. For example, many design systems allow the designer to input the number of gate fingers and the gate width as parameters for a particular transistor.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A semiconductor structure, comprising:
a stack of transistors connected in series, each having at least one drain region, at least one source region and one or more gate fingers; and
wherein a number of gate fingers is not constant for all transistors in the stack.

2. The semiconductor structure of claim 1, wherein the number of gate fingers is selected such that a voltage across each transistor in the stack is roughly equal when the transistors are in an OFF state.

3. The semiconductor structure of claim 1, wherein the source region of a last transistor is connected directly or indirectly to ground and has a second number of gate fingers, and a first transistor in the stack is furthest from the last transistor and has a first number of gate fingers, and wherein the first number is greater than the second number.

4. The semiconductor structure of claim 3, further comprising at least one transistor in series between the first transistor and the last transistor, having a number of gate fingers that is between the first number and the second number, inclusive.

5. The semiconductor structure of claim 4, wherein a number of gate fingers in each transistor decreases moving from the first transistor to the last transistor.

6. The semiconductor structure of claim 1, wherein the semiconductor structure comprises a shunt transistor stack.

7. The semiconductor structure of claim 1, wherein the semiconductor structure comprises a series transistor stack.

8. A semiconductor structure, comprising:
a stack of transistors connected in series, each having a gate width, at least one drain region, at least one source region and one or more gate fingers; and
wherein the gate width is not constant for all transistors in the stack.

9. The semiconductor structure of claim 8, wherein the gate width is selected such that a voltage across each transistor in the stack is roughly equal when the transistors are in an OFF state.

10. The semiconductor structure of claim 8, wherein the source region of a last transistor is connected directly or indirectly to ground and has a second gate width and a first transistor in the stack is furthest from the last transistor and has a first gate width, and wherein the first gate width is greater than the second gate width.

11. The semiconductor structure of claim 10, further comprising at least one transistor in series between the first transistor and the last transistor, having a gate width that is between the first gate width and the second gate width, inclusive.

12. The semiconductor structure of claim 11, wherein the gate width of each transistor decreases moving from the first transistor to the last transistor.

13. The semiconductor structure of claim 8, wherein the semiconductor structure comprises a shunt transistor stack.

14. The semiconductor structure of claim 8, wherein the semiconductor structure comprises a series transistor stack.

15. The semiconductor structure of claim 10, wherein a number of gate fingers is constant for all transistors in the stack.

16. The semiconductor structure of claim 10, wherein a number of gate fingers is not constant for all transistors in the stack.

17. The semiconductor structure of claim 16, wherein the last transistor has a second number of gate fingers and a first transistor has a first number of gate fingers, and wherein the first number of gate fingers is greater than the second number of gate fingers.

18. The semiconductor structure of claim 16, wherein the semiconductor structure comprises a shunt transistor stack.

19. The semiconductor structure of claim 16, wherein the semiconductor structure comprises a series transistor stack.
